(19) United States
(12) Patent Application Publication
(10) Pub. No.: US 2022/0345128 A1
(43) Pub. Date: Oct. 27, 2022

(54) GATE DRIVE CIRCUIT, INSULATED GATE DRIVER AND GATE DRIVE METHOD

(71) Applicant: Panasonic Intellectual Property Management Co., Ltd., Osaka (JP)

(72) Inventors: Yuta NAGATOMI, Kyoto (JP); Shingo ENOMOTO, Osaka (JP); Songbaek CHOE, Osaka (JP); Osamu TABATA, Osaka (JP); Noboru NEGORO, Osaka (JP)

(21) Appl. No.: 17/640,980

(22) PCT Filed: Dec. 7, 2020
(86) PCT No.: PCT/JP2020/045412

§ 371 Date: Mar. 7, 2022

(30) Foreign Application Priority Data
Dec. 12, 2019 (JP) 2019-224870

(51) Int. Cl. H03K 17/567; H03K 17/06; H03K 17/16; H02M 1/00

(52) U.S. Cl. CPC H03K 17/567; H03K 17/063; H03K 17/163; H02M 1/0029; H03K 2217/0081

(57) ABSTRACT

A gate drive circuit that drives a power device by controlling charge and discharge of gate capacitance of the power device includes: a first semiconductor switch that charges the gate capacitance by being brought into conduction according to a first control signal; a second semiconductor switch that discharges the gate capacitance by being brought into conduction according to a second control signal; and a slew rate control circuit that is connected between a gate of the power device and a ground line, and controls a slew rate during discharge. The slew rate control circuit includes a capacitor and a third semiconductor switch connected in series. The third semiconductor switch is brought into conduction according to the second control signal.

### TECHNICAL FIELD

The present disclosure relates to a gate drive circuit, an insulated gate driver, and a gate drive method which drive a power device.

### BACKGROUND ART

In recent years, the development of power devices using silicon carbide (S C) and gallium nitride (GaN) has been accelerated. Enhancement of the power devices promotes every product, regardless of consumer products or industrial products, to further include electronics, and can also downsize and enhance those products at the same time. Direct-current circuit breakers that have been rapidly attracting attention in recent years for the application to, for example, DC transmission and nuclear fusion test devices are also expected to further enhance their performance by introduction of the power devices. Compared to conventional interruption methods using only mechanical contact, the combined application of mechanical contact and a power device enables quicker interruption. In order to control such a power device, a gate drive circuit is required. The gate drive circuit supplies a control signal to the gate terminal of a power device, and controls ON and OFF of the power device.

Patent Literature (PTL) 1 discloses a circuit that adjusts the slew rate of a gate voltage of a switching circuit by detecting a voltage of an output terminal of a gate drive circuit and providing feedback on the voltage. The circuit adjusts the slew rate around threshold voltage Vth low.

PTL 2 discloses a circuit that controls a slew rate which is configured to: detect a gate voltage of a power device; provide feedback for a timing controller in a gate drive circuit; and convert a control signal input to the gate drive circuit into an appropriate driving signal to charge and discharge.

PTL 3 discloses a circuit that adjusts the slew rate of start-up and termination of a power device as a result of controlling a rise time and a fall time of each of a high-side switch and a low-side switch included in a half bridge circuit in a gate bridge circuit, using pull-down resistors provided for the gates of the switches.

### CITATION LIST

### Patent Literature

[PTL 1] International Publication No. 2017/085885
[PTL 2] Japanese Unexamined Patent Application Publication No. 2014-75694
[PTL 3] International Publication No. 2019/054051

### SUMMARY OF INVENTION

### Technical Problem

However, in order to implement slew rate control according to conventional techniques, a gate resistor and a complicated control circuit are required. Consequently, it is difficult to provide a simple circuit configuration suitable for cost reduction.

The present disclosure is provided in view of the above, and aims to provide a gate drive circuit, an insulated gate driver, and a gate drive circuit which are capable of performing optimal slew rate control in switching operation with a simple circuit configuration suitable for cost reduction, without including a gate resistor and a complicated control circuit.

### Solution to Problem

A gate drive circuit according to an aspect of the present disclosure is a gate drive circuit that drives a power device by charging and discharging gate capacitance of the power device. The gate drive circuit includes: a first semiconductor switch that charges the gate capacitance by being brought into conduction according to a first control signal; a second semiconductor switch that discharges the gate capacitance by being brought into conduction according to a second control signal; and a slew rate control circuit that is connected between a gate of the power device and a ground line, and controls a slew rate during the discharge. The slew rate control circuit includes a capacitor and a third semiconductor switch connected in series, and the third semiconductor switch is brought into conduction according to the second control signal.

In addition, an insulated gate driver according to an aspect of the present disclosure includes: the above-described gate drive circuit; a modulation circuit that modulates a radio frequency signal for electric power transmission by superimposing a switch control signal on the radio frequency signal; an insulated transmitter element that directly insulates and transmits a modulated radio frequency signal output from the modulation circuit; a rectifier circuit that extracts electric power and the switch control signal by rectifying a modulated radio frequency signal output from the insulated transmitter element; a power supply circuit that supplies a supply voltage to the first semiconductor switch, based on the electric power extracted by the rectifier circuit; a control circuit that generates the first control signal, based on the switch control signal; and a control circuit that generates the second control signal, based on the switch control signal.

Moreover, a gate drive method according to an aspect of the present disclosure is a gate drive method for a gate drive circuit that drives a power device by charging and discharging gate capacitance of the power device. The gate drive circuit includes: a first semiconductor switch that charges the gate capacitance by being brought into conduction according to a first control signal; a second semiconductor switch that discharges the gate capacitance by being brought into conduction according to a second control signal; and a slew rate control circuit that is connected between a gate of the power device and a ground line, and controls a slew rate during the discharge. The slew rate control circuit includes a capacitor and a third semiconductor switch connected in series. The gate drive method includes: causing discharge (i) from the gate capacitance to the ground line and (ii) from the gate capacitance to the capacitor by bringing the second semiconductor switch and the third semiconductor switch into conduction according to the second control signal; and causing the discharge from the gate capacitance to the ground line to continue at a slew rate slower than a slew rate at which the discharge from the gate capacitance to the capacitor is performed, after the discharge from the gate capacitance to the capacitor ceases.

### Advantageous Effects of Invention

According to a gate drive circuit, an insulated gate driver, and a gate drive method of the present disclosure, it is possible to implement optimal slew rate control in switching operation, with a simple circuit configuration suitable for cost reduction.

### BRIEF DESCRIPTION OF DRAWINGS

FIG. 1 is a diagram illustrating an example of a configuration of a power switching system including a gate drive circuit according to an embodiment.

FIG. 2A is a diagram illustrating an example of a first circuit for effect comparison and evaluation.

FIG. 2B is a diagram illustrating an example of a second circuit for effect comparison and evaluation.

FIG. 2C is a circuit diagram for verification of a drive waveform of the gate drive circuit according to the embodiment.

FIG. 3 Parts (a) through (c) of FIG. 3 illustrate time charts of respective operation waveforms when a power device is driven using gate drive circuits illustrated in FIG. 2A through FIG. 2C.

FIG. 4 is a diagram illustrating an example of a configuration of a power switching system including a gate drive circuit according to Variation 1 of the embodiment.

FIG. 5 is a diagram illustrating an example of a configuration of a power switching system including a gate drive circuit according to Variation 2 of the embodiment.

FIG. 6 is a circuit diagram illustrating an example of a configuration of an insulated gate driver according to the embodiment.

### DESCRIPTION OF EMBODIMENTS

### Background of Attaining Aspect of the Present Disclosure

The inventors have found out about occurrences of the following problems relating to gate drive circuits described in the background art section.

For example, in a direct-current circuit breaker that uses mechanical contact and a power device in combination, the power device connected in parallel to the mechanic& contact is switched to the ON state in the first place to suppress an arc of the mechanical contact when an anomaly occurs. The mechanical contact is switched to the OFF state after a commutation path is secured as described above. This increases, with time, a short-circuit current flowing through the power device, and thus may affect peripheral devices.

Accordingly, switching of the power device to the OFF state is required to be performed as quickly as possible. On the other hand, quick switching of the power device to the OFF state increases the amount of change in voltage and current applied across a device per time, and a surge occurs due to energy accumulated in a parasitic inductance of a line. This creates a risk of damaging the device due to an occurrence of ringing that exceeds a rated voltage of the power device, and may affect peripheral devices due to an occurrence of noise, Specifically, switching of a power device in a circuit breaker to the OFF state is to be ideally performed as quickly as possible at a speed below a speed at which a surge does not occur.

PTL 1 has a problem that the invention of PTL 1 requires a control circuit that is complicated and is capable of quick response for performing voltage detection and feedback control.

PTL 2 has a problem that a scale of a circuit tends to be large, since a gate voltage and current detection circuit and a timing controller of a power device are complicated.

Moreover, an adjustment that can be made to the configuration disclosed by PTL 3 is a speed at which electric charge is charged to and discharged from the gate of a power device, that is, only an adjustment to the slope, Specifically, the same problem as the case where a gate resistor is inserted, which is a representative slew rate control method, remains unresolved. Accordingly, the slew rate control disclosed by PTL 3 cannot be said as optimal slew rate control.

As a simple circuit configuration that controls a slew rate, provision of a gate resistor in series between a gate drive circuit and the gate terminal of a power device has been conventionally known. With this, an adjustment to a switching speed (hereinafter, slew rate) is made, that is, a measure for preventing an occurrence of ringing is taken by decreasing the amount of change in the voltage. However, provision of a gate resistor causes the following problems.

First, the switching speed is simply reduced. In order to switch a power device to the OFF state, electric charge accumulated in gate capacitance need to be discharged, A gate voltage decreases along with discharge of the electric charge, and the gate voltage causing an occurrence of a surge in this process is around threshold voltage Vth. In order to avoid a surge, a discharge amount of electric charge accumulated in the gate capacitance is to be decreased only when the gate voltage is around threshold voltage Vth to decrease the amount of change in the voltage and current applied across a power device per time. However, in the case where a gate resistor is inserted, the discharge amount of electric charge is uniformly limited throughout the discharge process. In other words, a surge can be prevented, but on the other hand, discharge in a gate voltage region irrelevant to a surge requires a long time.

Moreover, the connection of a gate resistor physically extends a line distance between a gate drive circuit and a power device, and thus a greater parasitic inductance occurs. Accordingly, a ringing component is likely to be added to a gate driving signal, and thus a problem may be caused in switching operation of the power device.

In view of the above, the present disclosure provides a gate drive circuit, an insulated gate driver, and a gate drive method which are capable of performing optimal slew rate control in switching operation with a simple circuit configuration suitable for cost reduction, not including a gate resistor and a complicated control circuit.

In order to provide such a gate drive circuit, a gate drive circuit according to an aspect of the present disclosure is a gate drive circuit that drives a power device by charging and discharging gate capacitance of the power device. The gate drive circuit includes: a first semiconductor switch that charges the gate capacitance by being brought into conduction according to a first control signal; a second semiconductor switch that discharges the gate capacitance by being brought into conduction according to a second control signal; and a slew rate control circuit that is connected between a gate of the power device and a ground line, and controls a slew rate during the discharge. The slew rate control circuit includes a capacitor and a third semiconductor switch connected in series, and the third semiconductor switch is brought into conduction according to the second control signal.

With this, it is possible to readily control a slew rate that reduces ringing, although the circuit has a simple circuit configuration. For example, a power device of a circuit breaker can be switched to the OFF state as quickly as possible at a speed below a speed at which a surge does not occur. In other words, an optimal slew rate adjustment can be made in switching of the power device to the OFF state.

In addition, an insulated gate driver according to an aspect of the present disclosure includes: the above-described gate drive circuit; a modulation circuit that modulates a radio frequency signal for electric power transmission by superimposing a switch control signal on the radio frequency signal; an insulated transmitter element that directly insulates and transmits a modulated radio frequency signal output from the modulation circuit; a rectifier circuit that extracts electric power and the switch control signal by rectifying a modulated radio frequency signal output from the insulated transmitter element; a power supply circuit that supplies a supply voltage to the first semiconductor switch, based on the electric power extracted by the rectifier circuit; a control circuit that generates the first control signal, based on the switch control signal; and a control circuit that generates the second control signal, based on the switch control signal.

Moreover, a gate drive method according to an aspect of the present disclosure is a gate drive method for a gate drive circuit that drives a power device by charging and discharging gate capacitance of the power device. The gate drive circuit includes: a first semiconductor switch that charges the gate capacitance by being brought into conduction according to a first control signal; a second semiconductor switch that discharges the gate capacitance by being brought into conduction according to a second control signal; and a slew rate control circuit that is connected between a gate of the power device and a ground line, and controls a slew rate during the discharge. The slew rate control circuit includes a capacitor and a third semiconductor switch connected in series. The gate drive method includes: causing discharge (i) from the gate capacitance to the ground line and (ii) from the gate capacitance to the capacitor by bringing the second semiconductor switch and the third semiconductor switch into conduction according to the second control signal; and causing the discharge from the gate capacitance to the ground line to continue at a slew rate slower than a slew rate at which the discharge from the gate capacitance to the capacitor is performed, after the discharge from the gate capacitance to the capacitor ceases.

Hereinafter, embodiments will be described in detail with reference to the drawings.

Note that the embodiments below each describe a general or specific example. The numerical values, shapes, materials, structural elements, the arrangement and connection of the structural elements, steps, and orders of the steps, etc, presented in the embodiments below are mere examples, and thus are not intended to limit the present disclosure. Therefore, among the structural elements in the following embodiments, structural elements not recited in any one of the independent claims are described as optional structural elements.

### EMBODIMENT

### 1.1 Configuration

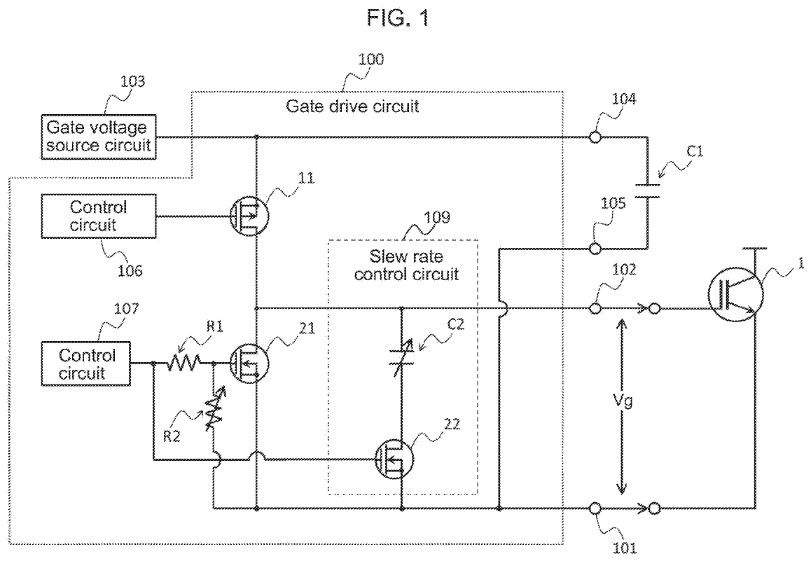

FIG. 1 is a diagram illustrating an example of a configuration of a power switching system including gate drive circuit 100 according to an embodiment. The power switching system illustrated in FIG. 1 includes power device 1, gate drive circuit 100, gate voltage source circuit 103, and capacitor C1.

In FIG. 1, power device 1 is a semiconductor switching element that can withstand pressure of, for example, several hundred volts. Power device 1 may be, for example, an insulated gate bipolar transistor (IGBT), a SiC field effect transistor (FET), or a gallium nitride (GaN) transistor.

Gate voltage source circuit 103 supplies supply voltage Vdd of gate drive circuit 100, that is, supply voltage Vdd for generation of gate voltage Vg.

Capacitor C1 is a capacitor for retaining supply voltage Vdd supplied from gate voltage source circuit 103, and smooths and stabilizes supply voltage Vdd.

Gate drive circuit 100 drives power device 1 by charging and discharging gate capacitance of power device 1. In other words, gate drive circuit 100 controls turning ON and OFF of power device 1 by selecting, according to an input signal, (i) whether or not to supply electric charge from supply voltage Vdd to the gate of power device 1, or (ii) whether or not to release electric charge charged to the gate terminal of power device 1.

Gate drive circuit 100 includes first semiconductor switch 11, second semiconductor switch 21, resistor R1, resistor R2, control circuit 106, control circuit 107, and slew rate control circuit 109. In addition, gate drive circuit 100 includes reference terminal 101, and output terminal 102 that outputs gate voltage Vg. Output terminal 102 is connected to the gate of power device 1. Reference terminal 101 is connected to a ground line and the source or the emitter terminal of power device 1.

In addition, gate drive circuit 100 includes terminal 104 connected to gate voltage source circuit 103, and terminal 105 connected to reference terminal 101. In between terminal 104 and terminal 105, capacitor C1 that stabilizes a gate voltage source is connected. This capacitor C1 may be included in a chip, or may be an external capacitor (i.e., an element provided outside a chip in which the circuit is formed) since the capacitor needs large capacitance in order to supply a peak current for stabilizing a voltage and to charge gate charge.

First semiconductor switch 11 and second semiconductor switch 21 are a high-side switch and a low-side switch, respectively, and are connected in series between supply voltage Vdd and the ground line. First semiconductor switch 11 and second semiconductor switch 21 generate a gate driving signal of power device 1 by switching operation.

First semiconductor switch 11 charges the gate capacitance of power device 1 by being brought into conduction according to first control signal S1 from control circuit 106. For example, first semiconductor switch 11 includes a pMOS transistor. The source of this pMOS transistor is connected to a line of supply voltage Vdd. The drain of the pMOS transistor is connected to second semiconductor switch 21. The gate of the pMOS transistor is connected to control circuit 106, and receives first control signal S1.

Second semiconductor switch 21 discharges the gate capacitance of power device 1 by being brought into conduction according to second control signal S2 from control circuit 107. Second semiconductor switch 21 includes, for example, an nMOS transistor. The drain of this nMOS transistor is connected to the drain of first semiconductor switch 11. The source of the nMOS transistor is connected to the ground line. The gate of the nMOS transistor is connected to control circuit 107, and receives second control signal S2.

Resistor R1 and resistor R2 are connected in series, and divide the voltage of second control signal S2 output from control circuit 107. From the connection point of resistor R1 and resistor R2, second control signal S2 whose voltage is divided is supplied to the gate of second semiconductor switch 21. The value of on-resistance of second semiconductor switch 21 can be set according to a value of the divided voltage. Moreover, the use of resistor R2 that serves as a variable resistor makes it possible to control the value of on-resistance of second semiconductor switch 21. The value of the on-resistance of second semiconductor switch 21 is used for controlling the slew rate of a gate driving signal (e.g., a fall in a gate voltage) of power device 1.

Control circuit 106 supplies first control signal S1 to the gate of first semiconductor switch 11.

Control circuit 107 supplies second control signal S2 to the gate of second semiconductor switch 21.

Slew rate control circuit 109 is connected between the gate of power device 1 and the ground line, and controls the slew rate during discharge. For this reason, slew rate control circuit 109 includes capacitor C2 and third semiconductor switch 22 which are connected in series.

Third semiconductor switch 22 is brought into conduction according to second control signal S2. Specifically, third semiconductor switch 22 is brought into conduction at the same timing as second semiconductor switch 21 is brought into conduction. Third semiconductor switch 22 causes discharge from the gate capacitance of power device 1 to capacitor C2 by being brought into conduction according to second control signal S2. A current via third semiconductor switch 22 causes electric charge to accumulate in capacitor C2, and thus electric potential is increased. However, since third semiconductor switch 22 controls a gate voltage based on reference terminal 101, third semiconductor switch 22 is not affected by potential variations due to charge of capacitor C2. For this reason, the connection of third semiconductor switch 22 and capacitor C2 are appropriate in the order shown in FIG. 1, In contrast, when capacitor C2 and third semiconductor switch 22 are connected in the order inverse of the order shown in FIG. 1, electric potential increases due to the charge of electric charge to capacitor C2. Accordingly, the control of third semiconductor switch 22 will be more difficult since third semiconductor switch 22 needs to be controlled along with electric potential of an upper electrode of capacitor C2.

At the same time, by being brought in to conduction according to second control signal S2, second semiconductor switch 21 causes the discharge from the gate capacitance to continue at a slew rate slower than a slew rate at which the discharge from the gate capacitance of power device 1 to capacitor C2 is performed, after the discharge from the gate capacitance of power device 1 to capacitor C2 ceases. As described, the slew rate can be controlled by a combination of quick discharge performed by third semiconductor switch 22 and second semiconductor switch 21 and slow discharge performed solely by second semiconductor switch 21.

In the example of the configuration illustrated in FIG. 1, a gate resistor is not provided between gate drive circuit 100 and power device 1. In other words, output terminal 102 of gate drive circuit 100 is directly connected with the gate of power device 1, not via a gate resistor.

In the example of the configuration illustrated in FIG. 1, first semiconductor switch 11 includes a normally-off pMOSFET. Moreover, second semiconductor switch 21 includes a normally-off nMOSFET. First semiconductor switch 11 has the drain connected to output terminal 102, and the source connected to capacitor C1 via terminal 104. Second semiconductor switch 21 has the drain connected to output terminal 102, and the source connected to reference terminal 101. The normally-off p-type MOSFET and the normally-off n-type MOSFET each allow a current to flow between the drain and the source, since resistance between the drain and the source is low when the gate potential is higher than and lower than the source potential. In order to stop the current to flow, the gate potential and the source potential of both p-type MOSFET and n-type MOSFET need to be equalized.

In addition, slew rate control circuit 109 is provided between output terminal 102 and reference terminal 101. Slew rate control circuit 109 is a serial connection circuit in which capacitor C2 and third semiconductor switch 22 are connected in series. Capacitor C2 has one terminal connected to output terminal 102, and the other terminal connected to the drain terminal of third semiconductor switch 22. In addition, third semiconductor switch 22 is a normally-off n-type MOSFET, and has the drain connected to one end of capacitor C2 and the source connected to reference terminal 101. According to the present disclosure, capacitor C2 is configured such that capacitor C2 can adjust a capacitance value. Here, capacitor C2 is specifically a capacitor having variable capacitance, such as a varicap whose electrostatic capacity changes due to a voltage and a MOS capacitor whose electrostatic capacity changes due to a voltage. Note that when power device 1 to be driven is predetermined, the capacitor need not be a capacitor having variable capacitance, and a capacitor whose capacitance value is fixed may be used.

Note that first semiconductor switch 11, second semiconductor switch 21, and third semiconductor switch 22 each may be a normally-on MOSFET transistor, and first semiconductor switch 11 may be an n-type MOSFET. Moreover, the foregoing need not be MOSFETs; each may be a transistor having a switching function capable of switching between ON and OFF. However, the normally-on type is unable to turn a transistor OFF unless a gate voltage is applied. Moreover, when an n-type MOSFET is used for first semiconductor switch 11, a gate voltage of the n-type MOSFET needs to be controlled following potential variations, since potential of output terminal 102 varies. Accordingly, the configuration of FIG. 1 is appropriate.

In addition, control circuit 106 that supplies first control signal S1 is provided at the gate of first semiconductor switch 11, and control circuit 107 that supplies second control signal S2 is provided for second semiconductor switch 21 and third semiconductor switch 22. Here, control circuit 107 and the gate terminal of second semiconductor switch 21 are connected via resistor R1, and control circuit 107 and the gate terminal of third semiconductor switch 22 are directly connected. Furthermore, resistor R2 is connected between the gate terminal of second semiconductor switch 21 and reference terminal 101. According to the present disclosure, resistor R2 includes a variable resistor such that resistor R2 can adjust a resistance value, Note that when power device 1 to be driven is predetermined, the resistor need not be a variable resistor, and a resistor whose resistance value is fixed may be used. Moreover, at least one of resistor R1 and resistor R2 may be a variable resistor. In addition, if the size of second semiconductor switch 21 is appropriate (i.e., on-resistance and a supplied current amount are appropriate), resistor R1 and resistor R2 need not be provided.

### 1.2 Operation

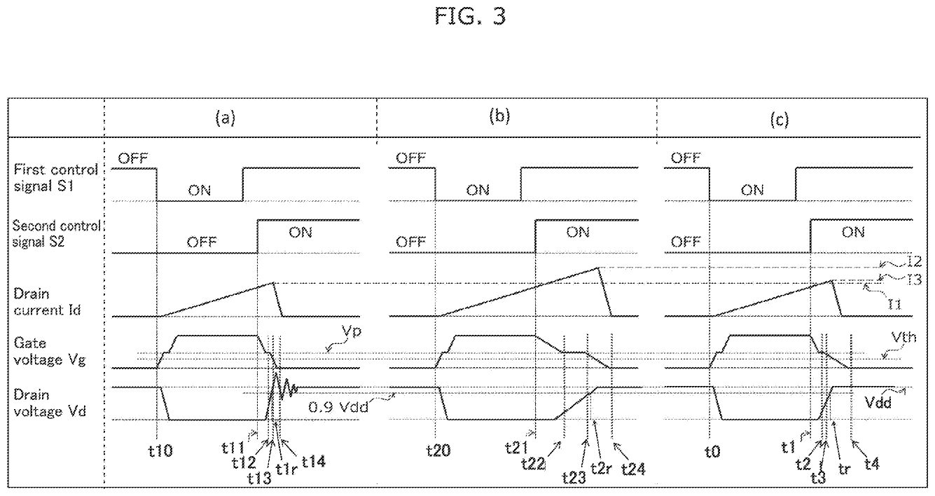

Next, as operation of gate drive circuit 100 illustrated in FIG. 1, discharge operation of discharging the gate capacitance of power device 1 will be mainly described with reference to (c) of FIG. 3. Part (c) of FIG. 3 is a time chart illustrating various operation waveforms of gate drive circuit 100, It should be noted that (a) and (b) of FIG. 3 will be described later. FIG. 3 illustrates a waveform of each of first control signal S1, second control signal S2, drain current Id of power device 1, gate voltage Vg of power device 1, and drain voltage Vd of power device 1.

Operation performed by gate drive circuit 100 to cause discharge of the gate capacitance of power device 1 is indicated from time t1 to time t4 shown in (c) of FIG. 3. Here, the discharge operation from time t1 to time t4 will be mainly described.

When first control signal S1 is brought into a high level just before time t1, that is, when a gate voltage of first semiconductor switch 11 and a source voltage are equalized by control circuit 106 just before time t1, first semiconductor switch 11 is brought into the OFF state.

When a period from time t1 to time t2 is a first period, quick discharge is possible in the first period.

Specifically, in order to start the discharge of the gate capacitance of power device 1 in time t1, second control signals S2 are supplied from control circuit 107 such that second semiconductor switch 21 and third semiconductor switch 22 are brought into the ON state. Here, second control signals S2 to be supplied from control circuit 107 to second semiconductor switch 21 and third semiconductor switch 22 may have the same timing, amplitude, duty, and cycle. In other words, two types of control signals need not be provided for controlling the two semiconductor switches.

When second semiconductor switch 21 and third semiconductor switch 22 are switched to the ON state, discharge of electric charge accumulated in the gate capacitance of the power device starts. This discharge is performed by a transfer of electric charge from the gate capacitance to capacitor C2, and by release of electric charge from the gate capacitance to reference terminal 101 via second semiconductor switch 21.

Here, the size of a transistor included in second semiconductor switch 21 may be smaller than that of third semiconductor switch 22 included in third semiconductor switch 22. This can relatively increase a current flowing through third semiconductor switch 22, and thus the slew rate due to the discharge performed by third semiconductor switch 22 can be increased, that is, the discharge can be quickly performed. On the contrary, it is possible to reduce a current flowing through second semiconductor switch 21, and thus the slew rate due to the discharge performed by second semiconductor switch 21 can be decreased, that is, the discharge can be slowly performed. Note that the size of a transistor here indicates a gate width.

In addition, the resistance value of resistor R1 may be adjusted, and the voltage of a second control signal supplied from control circuit 107 to second semiconductor switch 21 may be reduced to limit a current flowing between the drain and the source of second semiconductor switch 21. With this, when second semiconductor switch 21 and third semiconductor switch 22 are simultaneously turned ON, discharge of electric charge accumulated in the gate capacitance of power device 1 is performed dominantly by a transfer of electric charge to capacitor C2 in the first place, and is quickly performed.

Here, the gate capacitance of power device 1 can be considered as two classified capacitances, which are gate-to-source capacitance Cgs and gate-to-drain capacitance Cgd. Electric charge accumulated in the gate capacitance is discharged through the following processes.

First, discharge of gate-to-source capacitance Cgs occurs, and a gate voltage is decreased to the so-called plateau voltage Vp. A period from the start of the discharge to the gate voltage decreasing to plateau voltage Vp is the first period from time t1 to time t2.

When the gate voltage reaches plateau voltage Vp at time t2, the discharge of gate-to-source capacitance Cgs stops, and discharge of gate-to-drain capacitance Cgd starts. During the discharge of gate-to-drain capacitance Cgd, the gate voltage remains as plateau voltage Vp at a constant value, and does not vary until time t3 at which the discharge completes. A period from time t2 to time t3 is a Miller period, and is called a second period.

At time t3, when the discharge of gate-to-drain capacitance Cgd completes, the discharge of gate-to-source capacitance Cgs restarts and the gate voltage starts to decrease. The gate voltage decreases from plateau voltage Vp to reference potential through threshold voltage Vth, and the discharge of gate-to-source capacitance Cgs completes when the gate voltage reaches the reference potential at time t4. A period from time t3 to time t4 is called a third period.

Capacitor C2 plays a role in controlling a discharge amount to be discharged from the gate capacitance of power device 1 to proceed with the discharge process up to an optional stage. When the capacitance value of capacitor C2 is small, power device 1 does not shift to the Miller period (the discharge of gate-to-source capacitance Cgs in the first period does not complete), or the discharge from gate-to-drain capacitance Cgd does not proceed after the shift to the Miller period, and thus power device 1 does not get through the Miller period. On the contrary, when the capacitance value of capacitor C2 is large, the discharge of gate-to-drain capacitance Cgd completes, power device 1 gets through the Miller period, and the discharge of gate-to-source capacitance Cgs starts.

The capacitance value of capacitor C2 is to be set to a degree that the discharge of gate-to-drain capacitance Cgd completes. This is because the gate voltage remains as plateau voltage Vp until the discharge of gate-to-drain capacitance Cgd completes, and thus the gate voltage does not decrease to around threshold voltage Vth at which a surge occurs. Therefore, even if large current discharge is quickly performed during this period, ringing due to a surge does not occur.

When a transfer of electric charge to capacitor C2 completes, the discharge proceeds with only the release of electric charge from the gate capacitance of power device 1 to the reference terminal via second semiconductor switch 21. In this case, the resistance value of resistor R2 is adjusted to control the speed of discharging the gate capacitance such that ringing due to a surge does not occur.

With these elements, discharge from the gate capacitance of power device 1 can be switched between two stages, which are quick discharge and slow discharge, and performed, Specifically, quick discharge is performed in a gate voltage region irrelevant to a surge, and slow discharge is performed around threshold voltage Vth relevant to a surge.

Note that although control circuit 106 and control circuit 107 are separately illustrated in the drawing, a signal for controlling first semiconductor switch 11, and a signal for controlling second semiconductor switch 21 and third semiconductor switch 22 may be generated from the same signal. In this case, control circuit 106 additionally needs, for example, a circuit for adjusting a voltage level such that the p-type MOSFET can be controlled.

Moreover, in this case, a timing at which first semiconductor switch 11, and second semiconductor switch 21 and third semiconductor switch 22 are switched between ON and OFF is important. This timing also affects the slew rate of switching operation. For example, if second semiconductor switch 21 and third semiconductor switch 22 are turned ON before first semiconductor switch 11 is turned OFF, capacitor C2 is supplied with electric charge from gate voltage source circuit 103, and charge starts. Since second semiconductor switch 21 is limiting a current, an ability to be charged from gate voltage source circuit 103 exceeds the discharge ability. Accordingly, even if the charge of capacitor C2 is completed, the gate potential of power device 1 is equal to that of gate voltage source circuit 103. Even if first semiconductor switch 11 is turned OFF thereafter, the whole discharge process is performed solely by second semiconductor switch 21, Accordingly, the discharge will be extremely slowly performed. In order to avoid the foregoing, first semiconductor switch 11, and second semiconductor switch 21 and third semiconductor switch 22 are exclusively controlled such that first semiconductor switch 11, and second semiconductor switch 21 and third semiconductor switch 22 are not simultaneously turned ON.

### 1.3 Evaluation of Effect

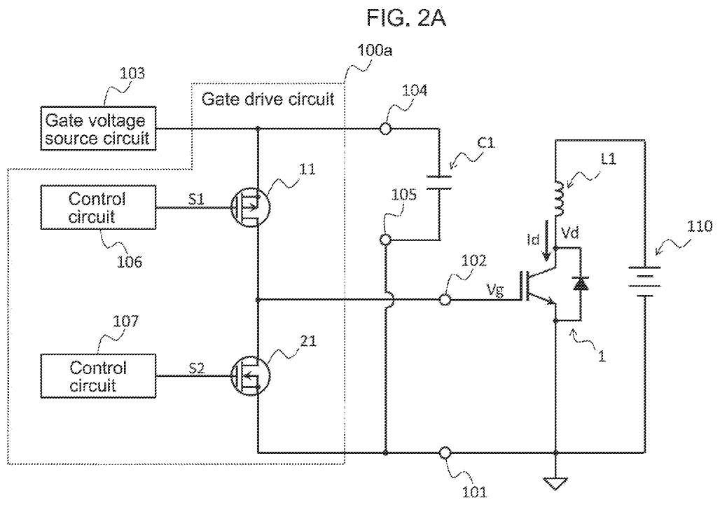

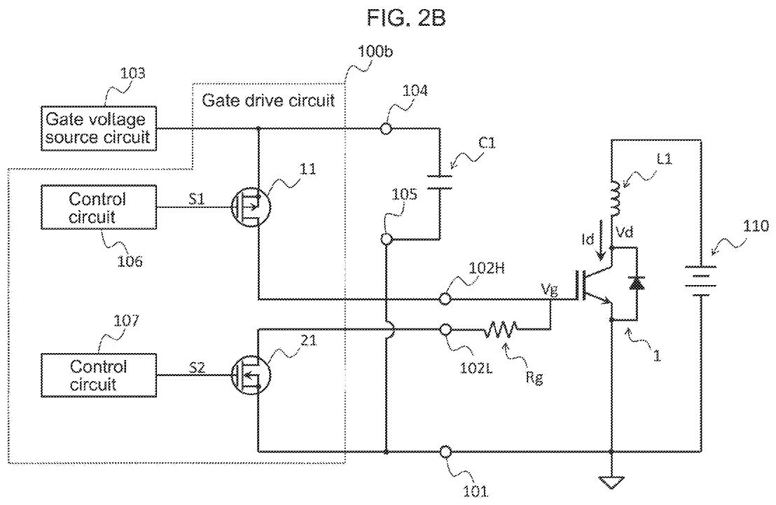

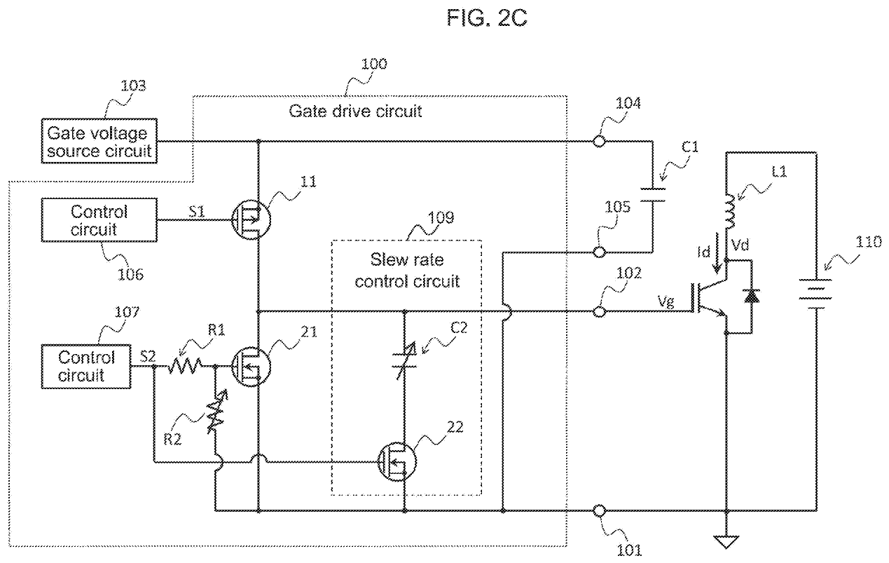

In order to evaluate effects of controlling the slew rate of gate drive circuit 100, the inventors of the present application have checked the operation of a power switching system using three types of gate drive circuits illustrated in FIG. 2A through FIG. 2C.

FIG. 2A is a diagram illustrating an example of a first circuit for effect comparison and evaluation. FIG. 2A illustrates a configuration from which slew rate control circuit 109, resistor R1, and resistor R2 are omitted from gate drive circuit 100 illustrated in FIG. 1, In other words, the example of the first circuit shown in FIG. 2A does not have a slew rate control function.

FIG. 2B is a diagram illustrating an example of a second circuit for effect comparison and evaluation. The example of the second circuit has a configuration to which resistor Rg is added to the example of the first circuit illustrated in FIG. 2A, In this circuit, a charge path and a discharge path are separately provided in gate drive circuit 100b to perform slew rate control only during discharge. An output terminal for charge is presented as 102H, and an output terminal for discharge is presented as 102L. Gate resistor Rg is inserted between the gate terminal of power device 1 and output terminal 102L for discharge.

FIG. 2C illustrates a configuration to which gate drive circuit 100 illustrated in FIG. 1 is applied.

These power switching systems each are intended to be a circuit breaker, and include supply voltage 110 and parasitic inductance L1 on a line.

The power switching systems illustrated in FIG. 2A through FIG. 2C operate as below. Note that a timing at which power device 1 is switched to the OFF state is a point in time at which drain voltage Vd has reached 90% of supply voltage Vdd.

Part (a) of FIG. 3 illustrates operation waveforms of gate drive circuit 100a illustrated in FIG. 2A. Part (b) of FIG. 3 illustrates operation waveforms of gate drive circuit 100b illustrated in FIG. 2B. Part (c) of FIG. 3 illustrates operation waveforms of gate drive circuit 100 illustrated in FIG. 2C. In (a) through (c) of FIG. 3, a period in which a gate voltage of a power device decreases from a high level to a plateau voltage during discharge is called a first period. A Miller period in which the gate voltage of the power device corresponds to a plateau voltage during the discharge is called a second period. A period in which the gate voltage decreases from a voltage at the end of the Miller period to a low level during the discharge is called a third period.

Since the circuit illustrated in FIG. 2A performs large current discharge, the switch to the OFF state is extremely quick. Each of the first period from time t11 to time t12, the second period from time t12 to time t13, and the third period from time t13 to time t14 is extremely short. However, since an amount of change in drain voltage Vd and drain current Id per time is remarkably large, large ringing has occurred. Large ringing can be a cause of a malfunction or a failure.

In the circuit illustrated in FIG. 2B, a discharge current is limited by gate resistor Rg. Accordingly, ringing of drain voltage Vd as illustrated in (a) of FIG. 3 has not occurred. However, since the discharge ability is low, each of the first period from time t21 to time t22, the second period from time t22 to time t23, and the third period from time t23 to time t24 is long. It took a long time to get through a Miller period, and thus the switch to the OFF state is slow.

In the circuit illustrated in FIG. 2C, as shown in (c) of FIG. 3, quick discharge to about threshold voltage Vth is performed by capacitor C2 in the first and second periods from time t1 to time t3. Thereafter, division of a voltage made by resistor R1 and resistor R2 limits a current of second semiconductor switch 21, and slow discharge is performed in the third period from time t3 to time t4, With this, power device 1 can be quickly switched to the OFF state while reducing ringing.

Note that the relation of the peak current of drain current Id is expressed as 12>13>11.

As has been described above, gate drive circuit 100 according to the embodiment can perform optimal slew rate control by (i) capacitor C2 performing quick discharge and making an adjustment to a discharge amount, and (ii) performing slow discharge by limiting a current of second semiconductor switch 21 using a voltage divided by resistor R1 and resistor R2. In addition, since the capacitance value of capacitor C2 plays a role in adjusting a discharge amount to be discharged via third semiconductor switch 22 and in stopping a current at the set gate voltage, a circuit for detecting a terminal voltage and a current of power device 1, a control circuit for determining a timing of supplying control signals based on feedback signals generated from the detection, etc. are not needed. In other words, the above-described configuration can perform switching control at an optimal timing, without using complicated circuits.

### 1.4 Variation 1

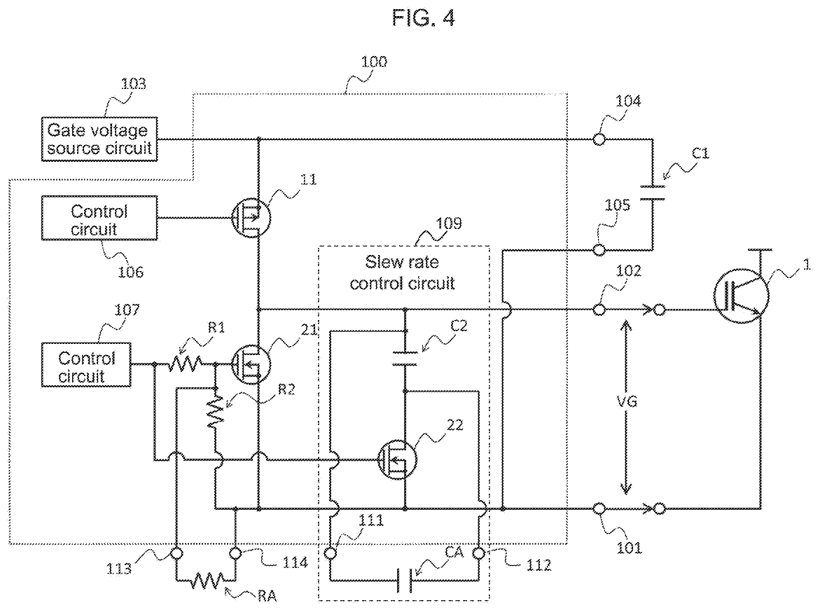

FIG. 4 is a diagram illustrating an example of a configuration of a power switching system including a gate drive circuit according to Variation 1 of the embodiment. The configuration illustrated in FIG. 4 is different from the configuration illustrated in FIG. 1 in that the configuration illustrated in FIG. 4 includes elements capable of capacitance value adjustment and resistor value adjustment. Specifically, the configuration illustrated in FIG. 4 includes external terminal 111 and external terminal 112 are provided for both ends of capacitor C2 such that external capacitor CA can be connected in parallel. With these elements, the capacitance connected between output terminal 102 and the drain of third semiconductor switch 22 has the combined capacitance value of capacitor C2 and capacitor CA, and the selection of external capacitor CA enables an adjustment to the capacitance value. Moreover, external terminals 113 and 114 are provided for both ends of resistor R2 such that external resistor RA can be connected in parallel. With these elements, the resistance connected between the gate of second semiconductor switch 21 and reference terminal 101 has the combined resistance value of resistor R2 and resistor RA, and the selection of external resistor RA enables an adjustment to the resistance value.

Note that capacitor C2 and resistor R2 may be excluded, and the power switching system may be configured such that the capacitance value and resistance value are adjusted solely by external capacitor CA and external resistor RA. In addition, in order to be able to adjust the capacitance value or the resistance value, the power switching system may be configured such that only one of an external capacitor and an external resistor is connectable.

### 1.5 Variation 2

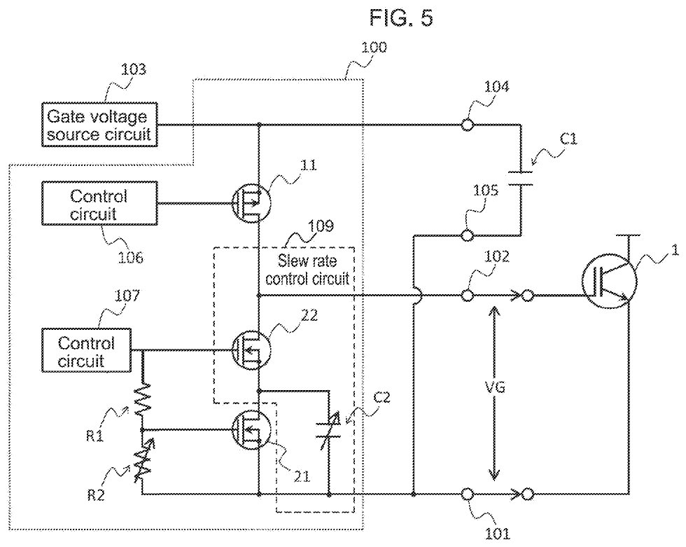

FIG. 5 is a diagram illustrating an example of a configuration of a power switching system including a gate drive circuit according to Variation 2 of the embodiment. The configuration illustrated in FIG. 5 is different from the configuration illustrated in FIG. 1 in that second semiconductor switch 21 has connection relationships different from the connection relationships illustrated in FIG. 1. Specifically, in the configuration illustrated in FIG. 5, the drain terminal of third semiconductor switch 22 is connected to output terminal 102, and the drain terminal of second semiconductor switch 21 is connected to the source terminal of third semiconductor switch 22.

In addition, one end of capacitor C2 is connected with the source terminal of third semiconductor switch 22, and the other end of capacitor C2 is connected with reference terminal 101. The size of third semiconductor switch 22 may be larger than that of second semiconductor switch 21, Moreover, an adjustment to the resistance value of resistor R2 can further reduce the current of second semiconductor switch 21.

With this configuration, slew rate control can be performed in the same manner as the slew rate control described in the embodiment. In other words, quick discharge is performed in the path between third semiconductor switch 22 and capacitor C2, and slow discharge after the quick discharge proceeds in the path between third semiconductor switch 22 and second semiconductor switch 21.

### 1.6 Configuration and Operation Characteristic of Insulated Gate Driver

Next, an example of a configuration of an insulated gate driver will be described as an application example of gate drive circuit 100.

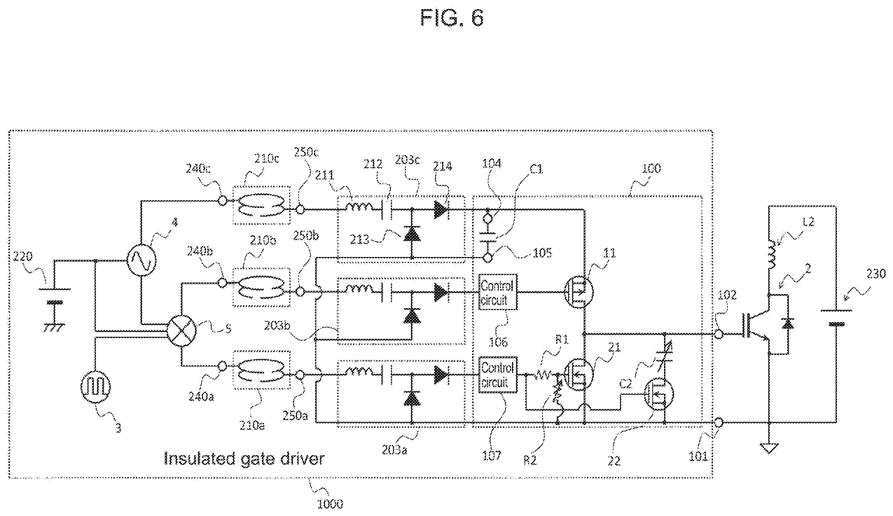

FIG. 6 is a circuit diagram illustrating insulated gate driver 1000 according to the embodiment. Insulated gate driver 1000 includes direct-current power supply 220, and signal generator 3, In addition, insulated gate driver 1000 includes radio frequency oscillation circuit 4, modulation circuit 5, first insulated transmitter 210a, terminals 240a and 250a of first insulated transmitter 210a for input and output, second insulated transmitter 210b, terminals 240b and 250b of second insulated transmitter 210b for input and output, third insulated transmitter 210c, and terminals 240c and 250c of third insulated transmitter 210c for input and output. Moreover, insulated gate driver 1000 includes rectifier circuit 203a through 203c, capacitor C1, gate drive circuit 100 illustrated in FIG. 1, output terminal 102, and reference terminal 101.

Insulated gate driver 1000 is a circuit that drives power device 2.

Power device 2 is a semiconductor switching element having the gate terminal (control terminal) connected to output terminal 102 of insulated gate driver 1000, and the source terminal connected to reference terminal 101. Note that power device 2 may be the same as power device 1 illustrated in FIG. 1.

Parasitic inductance L2 of a line is connected in series to power device 2. Specifically, one end of parasitic inductance L2 is connected to the drain terminal of power device 2. In addition, the positive terminal of direct-current power supply 230 is connected to the one end of parasitic inductance L2, and the negative terminal of direct-current power supply 230 is connected to the source terminal of power device 2.

Direct-current power supply 220 is a power supply for supplying electric power for each of radio frequency oscillation circuit 4 and modulation circuit 5 to operate.

Note that although direct-current power supply 220 is provided inside insulated gate driver 1000 in the configuration illustrated in FIG. 6, direct-current power supply 220 may be provided outside insulated gate driver 1000.

Signal generator 3 generates an input signal (control signal) for driving power device 2, and outputs the input signal to modulation circuit 5. Signal generator 3 includes, for example, a logic integrated circuit (IC). The input signal is a binary signal including a high-level signal and a low-level signal.

Note that although signal generator 3 is provided inside insulated gate driver 1000, signal generator 3 may be provided outside insulated gate driver 1000. In this case, insulated gate driver 1000 additionally includes an input terminal (not illustrated) to which an input signal from signal generator 3 is input.

Radio frequency oscillation circuit 4 generates a radio frequency signal. Radio frequency oscillation circuit 4 includes outputs for at least two channels, and outputs a radio frequency signal to each of modulation circuit 5 and third insulated transmitter 210c. Although 2.4 GHz and 5.8 GHz which are, for example, industrial, scientific and medical (ISM) bands that could be used without a license so long as the power is low are used as frequencies of radio frequency signals, other frequencies may be used. Radio frequency oscillation circuit 4 is, specifically, a Colpitts oscillator, a Hartley oscillator, and other oscillators that generate microwaves. It is desirable that radio frequency oscillation circuit 4 includes a frequency adjustment mechanism (not illustrated) in consideration of a variation in the frequency of a radio frequency signal. Note that a radio frequency signal that radio frequency oscillation circuit 4 generates is, in principle, a signal having predetermined amplitude and predetermined frequency. Note that although radio frequency oscillation circuit 4 is provided inside insulated gate driver 1000, radio frequency oscillation circuit 4 may be provided outside insulated gate driver 1000. In this case, insulated gate driver 1000 additionally includes an input terminal to which an input signal is input.

Modulation circuit 5 generates a first modulated signal that is a radio frequency signal modulated according to an input signal output by signal generator 3, and outputs the first modulated signal to first insulated transmitter 210a. Specifically, modulation circuit 5 generates a first modulated signal by mixing the above-mentioned input signal and radio frequency signal. Moreover, modulation circuit 5 generates a second modulated signal that is a radio frequency signal modulated according to a signal different from the input signal which is output by signal generator 3 and according to which the first modulated signal is generated, and outputs the second modulated signal to second insulated transmitter 210b. Specifically, modulation circuit 5 generates a second modulated signal by mixing a signal that is an input signal from signal generator 3 which is inverted and a radio frequency signal from radio frequency oscillation circuit 4. Although a first modulated signal and a second modulated signal keep a complementary relationship and are output, waveforms of these signals may be adjusted according to driving conditions.

Modulation circuit 5 is the so-called differential mixer (mixing circuit). It is suitable for insulated gate driver 1000, since a differential mixer can modulate a radio frequency signal with slight loss and can include several input and output terminals. Note that modulation circuit 5 may be a switching circuit. In the case where a switching circuit is used as the modulation circuit, a first modulated signal that is a radio frequency signal modulated and a second modulated signal that is a radio frequency signal modulated are generated by switching of an output destination of the radio frequency signal between first insulated transmitter 210a and second insulated transmitter 210b according to an input signal. Note that the input signal in this case is, for example, a complementary signal. Such a signal is implemented by signal generator 3 that includes a logic IC manufactured using a Si complementary metal oxide semiconductor (Si-CMOS) or a compound semiconductor. Note that the input signal may be a pulse width modulation (PWM) signal whose duty is inconstant. When a switching circuit is used as modulation circuit 5, isolation between output terminals of modulation circuit 5 improves. Moreover, since matching circuits for inductors, etc. are not necessary, it is possible to downsize insulated gate driver 1000.

First insulated transmitter 210a through third insulated transmitter 210c each are an electromagnetic resonance coupler. A radio frequency signal input from modulation circuit 5 is input from terminal 240a to first insulated transmitter 210a, and the signal that is insulated and transmitted is output from terminal 250a. An electromagnetic resonance coupler is also called an electromagnetic-field resonance coupler. Note that each of first insulated transmitter 210a through third insulated transmitter 210c is to be able to directly insulate and transmit a signal, and may be a transformer, for example.

In addition, a radio frequency signal input from modulation circuit 5 is input to second insulated transmitter 210b from terminal 240b, and the signal that is insulated and transmitted is output from terminal 250b.

Rectifier circuit 203c (third rectifier circuit) includes inductor 211, capacitor 212, and diodes 213 and 214.

In rectifier circuit 203c, inductor 211 has one end to which third insulated transmitter 210c is connected, and to which a radio frequency signal is input. This radio frequency signal is transmitted from radio frequency oscillation circuit 4 via third insulated transmitter 210c. The input radio frequency signal is rectified in rectifier circuit 203c, and is output from the cathode of diode 214 as a third signal. The output third signal charges capacitor C1. Capacitor C1 function as a power supply that supplies driving power for driving gate drive circuit 100 that will be described later. Moreover, as electric power of a radio frequency signal for charging capacitor C1, a relatively large electric power of, for example, at least 20 dBm is required.

Furthermore, rectifier circuit 203a (first rectifier circuit) and rectifier circuit 203b (second rectifier circuit) have an internal circuit configuration that is the same as the internal circuit configuration of rectifier circuit 203c (third rectifier circuit). Rectifier circuit 203a (first rectifier circuit) is connected with first insulated transmitter 210a. A first modulated signal is input to rectifier circuit 203a (first rectifier circuit), is rectified in rectifier circuit 203a, and is input to control circuit 107 as a first signal. A second modulated signal is input from second insulated transmitter 210b to rectifier circuit 203b (second rectifier circuit), is rectified in rectifier circuit 203b (second rectifier circuit), and is input to control circuit 106 as a second signal.

Gate drive circuit 100 includes first semiconductor switch 11, second semiconductor switch 21, third semiconductor switch 22, capacitor C2, resistors R1 and R2, and control circuits 106 and 107. Control circuit 106 supplies first control signal S1 to the gate of first semiconductor switch 11 according to a second signal output from rectifier circuit 203b, and supplies electric charge charged to capacitor C1 to the gate terminal (control terminal) of power device 2. Control circuit 107 supplies second control signal S2 to the gate of second semiconductor switch 21 and the gate of third semiconductor switch 22 according to a first signal output from rectifier circuit 203a, and extracts the electric charge at the gate terminal of power device 2. Specifically, gate drive circuit 100 selects, according to an input signal, (i) whether or not to supply electric charge charged to capacitor C1, that is, driving power, to the gate terminal of power device 2, or (ii) whether or not to release the electric charge charged to the gate terminal of power device 2.

Second semiconductor switch 21 is smaller in size than third semiconductor switch 22 to reduce a current. In addition, voltage division made by resistor R1 and resistor R2 decreases the voltage of second control signal S2 supplied from control circuit 107, thereby reducing the current value of second semiconductor switch 21.

In the state in which a first signal is input from rectifier circuit 203a to control circuit 107, and then second control signal S2 is supplied to the gate terminal of second semiconductor switch 21 and the gate terminal of third semiconductor switch 22, electric charge is charged to capacitor C1. However, since first semiconductor switch 11 is in the OFF state in the foregoing state, electric charge is not supplied to the gate of power device 2, and thus power device 2 is not brought into conduction.

When a first signal is not input from rectifier circuit 203a to control circuit 107, and a second signal is input to control circuit 106 and first control signal S1 is supplied to the gate terminal of first semiconductor switch 11, electric charge charged to capacitor C1 is supplied to the gate terminal of power device 2. Accordingly, power device 2 is brought into conduction, and a current flows into parasitic inductance L2, In this case, the current that flows into parasitic inductance L2 increases in proportion to time.

When a first signal is input from rectifier circuit 203a to control circuit 107 again, and then second control signal S2 is supplied to the gate terminal of second semiconductor switch 21 and the gate terminal of third semiconductor switch 22, electric charge accumulated in the gate terminal of power device 2 is discharged, to reference terminal 101 and capacitor C2, by second semiconductor switch 21 and third semiconductor switch 22. With this, power device 2 is brought out of conduction, and a current does not flow into parasitic inductance L2. In this case, since a current that flows into second semiconductor switch 21 is reduced by the size of second semiconductor switch 21 and resistor R2, discharge at the early stage is proceeded dominantly by capacitor C2.

The capacitance value of capacitor C2 is set to a degree that a gate voltage of power device 2 can complete a Miller period, With this, the gate voltage of power device 2 will not be decreased to threshold voltage Vth. Accordingly, large current discharge performed in this period readily makes it possible to quickly proceed with the discharge process. When the transfer of electric charge to capacitor C2 is completed, the discharge proceeds solely by second semiconductor switch 21. In this case, the speed of discharging the gate capacitance can be readily controlled by adjusting the resistance value of resistor R2, such that ringing due to a surge does not occur.

With these elements, the discharge from the gate capacitance of power device 2 can be switched between two stages, which are quick discharge and slow discharge, and performed, while electric power and a signal are insulated and transmitted. In other words, quick discharge is performed in a gate voltage region irrelevant to a surge, and slow discharge is performed around threshold voltage Vth relevant to a surge.

As has been described above, gate drive circuit 100 according to the embodiment is gate drive circuit 100 that drives a power device by controlling charge and discharge of gate capacitance of the power device. The gate drive circuit includes: first semiconductor switch 11 that charges the gate capacitance by being brought into conduction according to first control signal S1; second semiconductor switch 21 that discharges the gate capacitance by being brought into conduction according to second control signal S2; and slew rate control circuit 109 that is connected between a gate of the power device and a ground line, and controls a slew rate during the discharge. Slew rate control circuit 109 includes capacitor C2 and third semiconductor switch 22 connected in series, and third semiconductor switch 22 is brought into conduction according to second control signal S2.

With this, it is possible to reduce ringing and to readily control the slew rate, even with the simple circuit configuration.

Here, the size of a transistor included in third semiconductor switch 22 may be larger than the size of a transistor included in second semiconductor switch 21.

With this, it is possible to reduce a current flowing through second semiconductor switch 21, and thus the slew rate due to the discharge performed by second semiconductor switch 21 can be decreased, that is, the discharge can be slowly performed. Moreover, it is possible to relatively increase a current flowing through third semiconductor switch 22, and thus the slew rate due to the discharge performed by third semiconductor switch 22 can be increased, that is, the discharge can be quickly performed.

Here, the gate drive circuit may further include a first resistance element and a second resistance element connected in series which divide a voltage of second control signal S2. The second control signal whose voltage is divided may be input to a gate of the transistor included in second semiconductor switch 21, and the second control signal whose voltage is undivided may be input to a gate of the transistor included in third semiconductor switch 22.

With this, conduction resistance of second semiconductor switch 21 can be set according to a value of the divided voltage, and thus a current flowing through second semiconductor switch 21 can be reduced. In other words, it is possible to decrease, according to the value of the divided voltage, the slew rate due to the discharge performed by second semiconductor switch 21, that is, the discharge can be slowly performed.

Here, capacitor C2 may use a variable capacitance value.

With this, it is possible to readily control, according to a capacitance value, a discharge amount to be discharged from the gate capacitance to capacitor C2, by third semiconductor switch 22.

Here, the gate drive circuit may further include a first terminal (external terminal 111 in FIG. 4) and a second terminal (external terminal 112 in FIG. 4) which are for external capacitor connection. The first terminal may be connected to one end of capacitor C2, and the second terminal may be connected to the other end of capacitor C2.

With this, an external capacitor can readily control the slew rate due to discharge performed by third semiconductor switch 22.

Here, one end of second semiconductor switch 21 may be connected to the gate of the power device, and the other end of second semiconductor switch 21 may be connected to the ground line. The one end here corresponds to one of the source and the drain of second semiconductor switch 21, and the other end corresponds to the other one of the source and the drain of second semiconductor switch 21.

Accordingly, a circuit configuration in which slew rate control circuit 109 and second semiconductor switch 21 are connected in parallel can be formed. The slew rate control enables quick discharge to be performed by third semiconductor switch 22 and capacitor C2, and slow discharge that takes place after the quick discharge to be performed by second semiconductor switch 21.

Here, one end of third semiconductor switch 22 may be connected to the gate of the power device, the other end of third semiconductor switch 22 may be connected to one end of capacitor C2, the other end of capacitor C2 may be connected to the ground line, and second semiconductor switch 21 may be connected between the other end of third semiconductor switch 22 and the ground line. The one end here corresponds to one of the source and the drain of third semiconductor switch 22, and the other end corresponds to the other one of the source and the drain of third semiconductor switch 22.

Even with this circuit configuration, the slew rate control enables quick discharge to be performed by third semiconductor switch 22 and capacitor C2, and slow discharge that takes place after the quick discharge to be performed by second semiconductor switch 21.

Here, when (i) a first period is a period in which a gate voltage of the power device decreases from a high level to a plateau voltage during the discharge, (ii) a second period is a Miller period in which the gate voltage corresponds to the plateau voltage during the discharge, and (iii) a third period is a period in which the gate voltage decreases from a voltage at an end of the Miller period to a low level during the discharge, slew rate control circuit 109 may control the gate voltage to cause a slope of the gate voltage in the first period to be greater than a slope of the gate voltage in the third period.

With this, the slew rate control enables quick discharge to be performed by third semiconductor switch 22 and capacitor C2 in the first period, and slow discharge to be performed by second semiconductor switch 21 in the third period after the first period.

In addition, insulated gate driver 1000 according to the embodiment includes: the above-described gate drive circuit 100; modulation circuit 5 that modulates a radio frequency signal for electric power transmission by superimposing a switch control signal on the radio frequency signal; insulated transmitter elements 210a through 210c each of which directly insulates and transmits a modulated radio frequency signal output from modulation circuit 5; rectifier circuits 203a through 203c each of which extracts electric power and the switch control signal by rectifying a modulated radio frequency signal output from an insulated transmitter element among the insulated transmitter elements; a power supply circuit (gate voltage source circuit 103) that supplies a supply voltage to the first semiconductor switch, based on the electric power extracted by an rectifier circuit among the rectifier circuits; control circuit 106 that generates the first control signal, based on the switch control signal; and control circuit 107 that generates the second control signal, based on the switch control signal.

With this, it is possible to reduce ringing and to readily control the slew rate, even with the simple circuit configuration.

In addition, a gate drive method according to the embodiment is a gate drive method for gate drive circuit 100 that drives a power device by charging and discharging gate capacitance of the power device. Gate drive circuit 100 includes: first semiconductor switch 11 that charges the gate capacitance by being brought into conduction according to first control signal S1; second semiconductor switch 21 that discharges the gate capacitance by being brought into conduction according to second control signal S2; and slew rate control circuit 109 that is connected between a gate of the power device and a ground line, and controls a slew rate during the discharge. Slew rate control circuit 109 includes capacitor C2 and third semiconductor switch 22 connected in series. The gate drive method includes: causing discharge (i) from the gate capacitance to the ground line and (ii) from the gate capacitance to capacitor C2 in a high slew rate by bringing second semiconductor switch 21 and third semiconductor switch 22 into conduction according to second control signal S2; and causing the discharge from the gate capacitance to the ground line to continue at a slew rate slower than a slew rate at which the discharge from the gate capacitance to capacitor C2 is performed, after the discharge from the gate capacitance to the capacitor ceases.

With this, it is possible to reduce ringing and to readily control the slew rate, even with the simple circuit configuration.

As has been described above, a gate drive circuit, an insulated gate driver, and a gate drive method according to the present disclosure can implement optimal slew rate control in switching operation, with a simple circuit configuration suitable for cost reduction. For example, a power device of a circuit breaker can switch to the OFF state as quickly as possible at a speed below a speed at which a surge does not occur. In other words, an optimal slew rate adjustment is possible in the switching of the power device to the OFF state.

### INDUSTRIAL APPLICABILITY

Since a gate drive circuit according to the present disclosure enables an adjustment to a slew rate in switching operation without providing a gate resistor, it is useful for downsizing a power switching system, for example.

### REFERENCE SIGNS LIST

5 modulation circuit
11 first semiconductor switch
21 second semiconductor switch
22 third semiconductor switch
100 gate drive circuit
106, 107 control circuit
109 slew rate control circuit
111 external terminal (first terminal)
112 external terminal (second terminal)
210a to 210c insulated transmitter (insulated transmitter
element)
203a to 203c rectifier circuit
1000 insulated gate driver
C2 capacitor
R1, R2 resistor

1. A gate drive circuit that drives a power device by controlling charge and discharge of gate capacitance of the power device, the gate drive circuit comprising:
a first semiconductor switch that charges the gate capacitance by being brought into conduction according to a first control signal;
a second semiconductor switch that discharges the gate capacitance by being brought into conduction according to a second control signal; and
a slew rate control circuit that is connected between a gate of the power device and a ground line, and controls a slew rate during discharge of the gate capacitance, wherein
the slew rate control circuit includes a capacitor and a third semiconductor switch connected in series, and
the third semiconductor switch is brought into conduction according to the second control signal.

2. The gate drive circuit according to claim 1, wherein
a size of a transistor included in the third semiconductor switch is larger than a size of a transistor included in the second semiconductor switch.

3. The gate drive circuit according to claim 1, further comprising:
a first resistance element and a second resistance element connected in series which divide a voltage of the second control signal, wherein
the second control signal whose voltage is divided is input to a gate of a transistor included in the second semiconductor switch, and
the second control signal whose voltage is undivided is input to a gate of a transistor included in the third semiconductor switch.

4. The gate drive circuit according to claim 1, wherein
the capacitor has a variable capacitance value.

5. The gate drive circuit according to claim 1, further comprising:
a first terminal and a second terminal which are for external capacitor connection, wherein
the first terminal is connected to one end of the capacitor, and
the second terminal is connected to an other end of the capacitor.

6. The gate drive circuit according to claim 1, wherein
one end of the second semiconductor switch is connected to the gate of the power device, and
an other end of the second semiconductor switch is connected to the ground line.

7. The gate drive circuit according to claim 1, wherein
one end of the third semiconductor switch is connected to the gate of the power device,
an other end of the third semiconductor switch is connected to one end of the capacitor,
an other end of the capacitor is connected to the ground line, and
the second semiconductor switch is connected between the other end of the third semiconductor switch and the ground line.

8. The gate drive circuit according to claim 1, wherein
when (i) a first period is a period in which a gate voltage of the power device decreases from a high level to a plateau voltage during the discharge, (ii) a second period is a Miller period in which the gate voltage corresponds to the plateau voltage during the discharge, and (iii) a third period is a period in which the gate voltage decreases from a voltage at an end of the Miller period to a low level during the discharge,
the slew rate control circuit controls the gate voltage to cause a slope of the gate voltage in the first period to be greater than a slope of the gate voltage in the third period.

9. An insulated gate driver comprising:
the gate drive circuit according to claim 1;
a modulation circuit that modulates a radio frequency signal for electric power transmission by superimposing a switch control signal on the radio frequency signal;
an insulated transmitter element that directly insulates and transmits a modulated radio frequency signal output from the modulation circuit;
a rectifier circuit that extracts electric power and the switch control signal by rectifying modulated radio frequency signal output from the insulated transmitter element;
a power supply circuit that supplies a supply voltage to the first semiconductor switch, based on the electric power extracted by the rectifier circuit;
a control circuit that generates the first control signal, based on the switch control signal; and
a control circuit that generates the second control signal, based on the switch control signal.

10. A gate drive method for a gate drive circuit that drives a power device by charging and discharging gate capacitance of the power device, wherein
the gate drive circuit includes:
a first semiconductor switch that charges the gate capacitance by being brought into conduction according to a first control signal;
a second semiconductor switch that discharges the gate capacitance by being brought into conduction according to a second control signal; and
a slew rate control circuit that is connected between a gate of the power device and a ground line, and controls a slew rate during discharge of the gate capacitance,
the slew rate control circuit includes a capacitor and a third semiconductor switch connected in series, and
the gate drive method comprises:
causing discharge (i) from the gate capacitance to the ground line and (ii) from the gate capacitance to the capacitor by bringing the second semiconductor switch and the third semiconductor switch into conduction according to the second control signal; and
causing the discharge from the gate capacitance to the ground line to continue at a slew rate slower than a slew rate at which the discharge from the gate capacitance to the capacitor is performed, after the discharge from the gate capacitance to the capacitor ceases.
